(19) United States
(12) Patent Application Publication
(10) Pub. No.: US 2001/0036279 A1
(43) Pub. Date: Nov. 1, 2001

(54) Active noise cancellation system

(76) Inventor: Paul D. Daly, Troy, MI (US)

Correspondence Address: Anthony P. Cho, Carlson, Gaskey & Olds, P.C., Ste. 350, 400 W. Maple Rd., Birmingham, MI, 48009, US

(21) Appl. No.: 09/792,956

(22) Filed: Feb. 26, 2001

Related U.S. Application Data
(60) Provisional application No. 60/202,385, filed on May 8, 2000.
(60) Provisional application No. 60/202,386, filed on May 8, 2000.

(51) Int. Cl. H03B 29/00

(52) U.S. Cl. 381/71.4; 381/94.1

(57) ABSTRACT

The air induction system comprises an air intake and speaker disposed about the air intake. A control unit is in communication with the speaker. At least one receiver permits communication between the control unit and at least one powertrain input. An engine computer may communicate the powertrain input to the receiver and prevent such communication at a predetermined threshold based on engine load.

This application claims priority to Provisional Patent Application Ser. No. 60/202,385 filed May 8, 2000 and Provisional Patent Application Ser. No. 60/202,386 filed May 8, 2000.

### BACKGROUND OF THE INVENTION

1. This invention relates to an active manner of controlling automotive induction noise.

2. Manufacturers have employed active and passive methods to reduce engine noise within the passenger compartment. Such noise frequently emanates from the engine, travels through the air induction system and emanates out of the mouth of the air intake into the passenger compartment. Efforts have been made to reduce the amount of engine noise traveling through the air induction system. These efforts include the use of both passive devices such as expansion chambers and Helmholtz resonators and active devices involving anti-noise generators.

3. Active systems use a speaker to create a sound that attenuates engine noise. The speaker generates a sound that is out of phase with the engine noise and that combines with the engine noise to result in its reduction. This cancellation signal is generated in proximity to the air induction system.

4. In one such system, the cancellation signal is generated by a digital signal processor. Such a system may require input from such sensors as an engine crank sensor, a throttle position sensor, or other powertrain indicators. However, these sensors are typically connected to the engine control unit rather than directly to the digital signal processor used for noise cancellation. The engine control unit and digital signal processor are generally located apart from each other. Consequently, a separate communication link is required to communicate input obtained from powertrain sensors and received by the engine control unit to the digital signal processor of the noise cancellation system. Because of the volume of data communicated from these sensors, the link requires changes to the engine computer and its software as well as wiring. Moreover, continuous transmission of such data even when the engine is idling or at low loads results in the active noise cancellation system creating a high pitch noise when no noise cancellation is even required.

5. A need therefore exists for a simplified way of communicating information from the powertrain to the digital signal processor of the noise cancellation system.

### SUMMARY OF THE INVENTION

6. In a disclosed embodiment of this invention, the air induction system permits wireless communication of data from the powertrain to the noise cancellation control unit. The transmission of such data can be limited to the condition when the engine experiences a predetermined load sufficient to require noise cancellation. In this way, communication to the control unit is greatly simplified.

7. The air induction system comprises an air intake and a speaker disposed about the air intake. A control unit is in communication with the speaker. A receiver receives powertrain input and communicates this data to the control unit. The powertrain input can be a crank position data, fuel injection data, or ignition data. With respect to fuel injection systems and ignition systems, such data may be obtained simply by using a receiver to “pick up” the electromagnetic inductive pulses emitted by these systems. Because these pulses have unique signatures, they may be simply received rather than transmitted by a transmitter and then received. However, a sensor and transmitter may be employed nevertheless to facilitate the communication of the data to the receiver. A microphone serves as further input to the control unit.

8. The system may work in conjunction with an engine computer. In such an instance, the powertrain input is communicated to the engine computer and then communicated to the receiver and ultimately the control unit. The engine computer may withhold the communication of data until a predetermined engine load threshold is reached thereby limiting the amount of data communicated.

9. Moreover, the system may do without a receiver and comprise an engine computer in communication with the control unit and at least one powertrain input. In this particular configuration, the powertrain input is communicated to the engine computer, which then decides whether to communicate this data to the control unit. The engine computer bases this decision on the amount of engine load detected by the computer.

10. The foregoing system thus permits control over the amount of data transmitted to the control unit. Moreover, the system also provides a convenient way to communicate such data without the communication links otherwise required. Finally, the system requires no significant modification of the engine computer to accomplish these ends.

### BRIEF DESCRIPTION OF THE DRAWINGS

11. The various features and advantages of this invention will become apparent to those skilled in the art from the following detailed description of the currently preferred embodiment. The drawings that accompany the detailed description can be briefly described as follows:

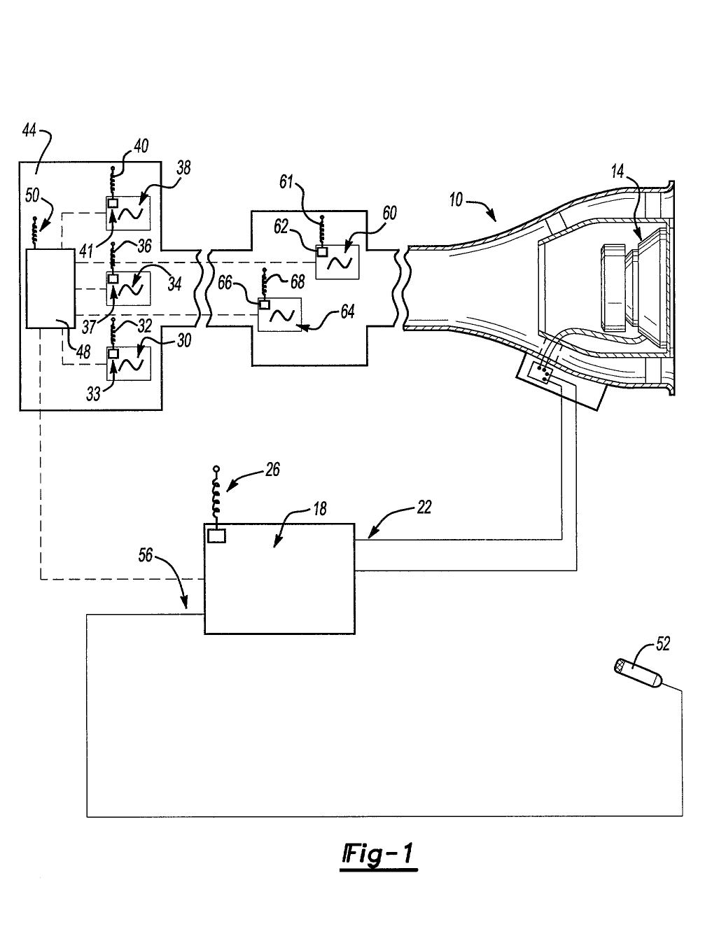

12. FIG. 1 shows a schematic view of an embodiment of the invention.

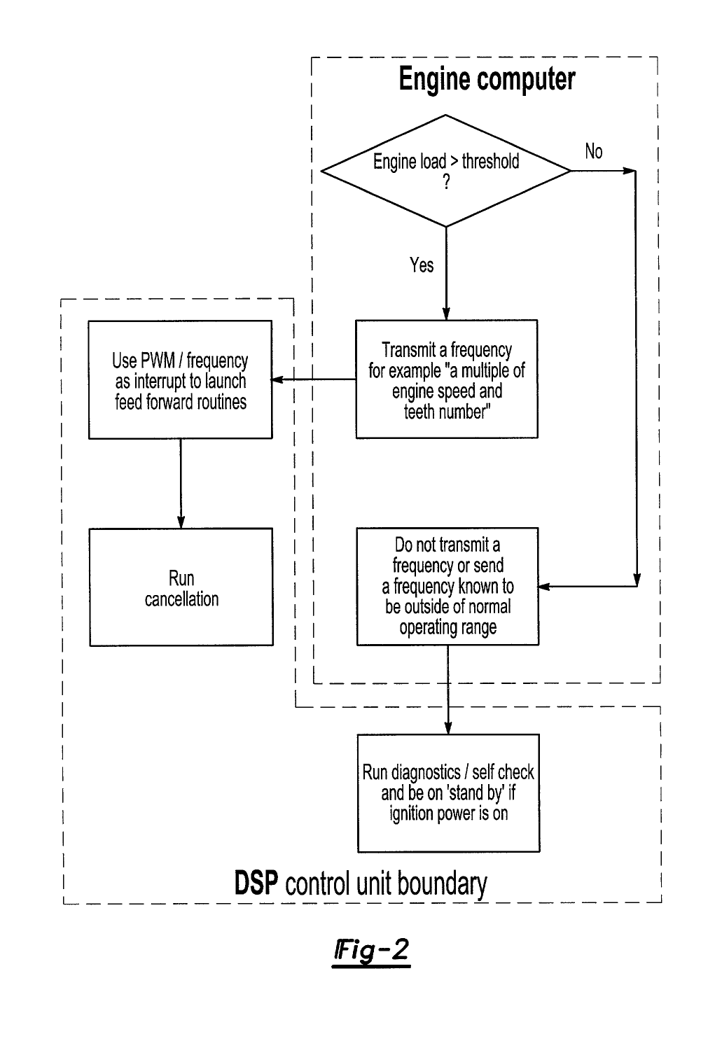

13. FIG. 2 shows a flow chart of the process an embodiment of the invention.

### DETAILED DESCRIPTION OF THE PREFERRED EMBODIMENT

14. FIG. 1 illustrates a schematic embodiment of the invention. Shown are air intake 10 and speaker 14 disposed about air intake 10. Control unit 18 is in communication with speaker 14. At least one receiver 26 is in communication with control unit 18, which includes a digital signal processor, and permits reception of at least one powertrain input such as crank position data 30, fuel injection data 34, or ignition data 38. As known in the art, control unit 18 uses this data to model the engine and thereby attenuate engine noise through speaker 14.

15. The invention relates to the communication of crank position data 30, fuel injection data 34, and ignition data 38 to control unit 18. In one embodiment of the invention, communication is facilitated and simplified by employing receiver 26 to pick up this data without communication hardwires (non-hardwired). In another embodiment the communication of this data is limited to instances where such data is required by control unit 18. The latter embodiment may be accomplished without hardwires or with hardwires.

16. With respect to communication without hardwires, communication with control unit 18 may be facilitated by transmitter 32, 36, or 40. However, with respect to fuel injection data 34 and ignition data 38, this data may be received by receiver 26 without assistance from a transmitter. Indeed, because ignition systems typically use voltages of more than 20,000 volts while a fuel injection system employ voltages of 40 to 60 volts, these systems generate distinctive electromagnetic pulses that may be detected by receiver 26 without the assistance of a transmitter. These electromagnetic pulses themselves provide valuable data regarding engine speed and engine load, which is then used by control unit 18 to attenuate engine noise.

17. Fuel injection data 34 may be simply the electromagnetic inductive pulses created during the normal operation of the fuel injection system and the electronic ignition system. These inductive pulses are typically of radio wave frequency range and may be received by antenna 26, which is attuned to receive these signals. In this way, no transmitter is required.

18. A fuel injection system radiates an inductive pulse on the opening of each injector as well as its closing. The frequency of the pulses provides data regarding engine speed. Moreover, the time between these pulses is the injector “on time” and is directly proportional to load of engine 44. This “on time” is in the range of 2 to 20 milliseconds. The time such injectors are “off” may also be used to disable control unit 18 from canceling engine noise through speaker 14 to avoid creating the high pitch noise resulting from operation of the control unit at low engine loads. At very high speeds, say 6000 rpms and above, it is possible that the “on time” is equal to the period of one revolution of the engine. Nevertheless, an inductive pulse will still exist as the fuel injector computer will still attempt to turn the injectors “on” and “off”. In such a situation, it is possible to detect the “off” time remaining and if required disable noise cancellation to avoid errors or instability of the noise cancellation system. To receive such data, an antenna of receiver 26 may be wrapped around the connecting wires of the fuel injectors. Alternatively, sensor 37 may monitor fuel injection data and employ transmitter 36 to communicate this data to control unit 18.

19. Ignition data 38 may also be simply the electromagnetic inductive pulse radiating from the ignition system. Specifically, ignition timing communicates data concerning engine speed and load. As known in the art, for any particular engine, ignition timing may be related to engine speed and load. If the engine is of a known calibration, then for each speed as calculated by injection timing, the ignition delay can be measured. If ignition delay is measured then for a known engine calibration, the load can be deduced by the ignition timing. Although there is variation for fuel type, this variation will not be large enough to affect the load detection for purposes of enabling or disabling noise cancellation. While a sensor is not required to monitor the electromagnetic pulses of the ignition system, sensor 41 may be used to monitor ignition data 38 and employ transmitter 40 to communicate this data to control unit 18.

20. Crank position data 30 may be obtained by a sensor as known and communicate about engine speed and engine load. Transmitter 32 may then communicate this data to control unit 18. In this way, no wire is required to communicate this data. Further, no hardware or software modification need be made to the engine computer.

21. In this system, as known, error microphone 52 detects any sound not attenuated by the cancellation signal. Line 56 communicates the signal from error microphone to control unit 18. Control unit 18 uses this signal as feedback to determine whether further engine noise attenuation is required.

22. To reduce the amount of data communicated to control unit 18, powertrain input such as crank position data 30, ignition data 34, and fuel injector data 38 may be withheld from control unit 18 when such data is not required such as when the engine experiences a low load. Such powertrain data may also include data regarding the air temperature data 60 from air temperator sensor 62 as transmitted by transmitter 61 and throttle position data 64 from throttle position sensor 66 as transmitted by transmitter 68. This embodiment of the invention may employ all hardwires (as shown by dashed lines) rather than transmitters 32, 36, 40, or 50. However, such wiring will require modification of the engine computer and a fair amount of cabling.

23. In such an embodiment engine computer 48 receives the powertrain input. However, powertrain input is only communicated only when a predetermined threshold is reached. This predetermined threshold may be based on engine load. In other words, if the engine load is too low to require noise cancellation, then engine computer 48 does not communicate these powertrain inputs to control unit 18. If the predetermined threshold is reached, then engine computer 48 communicates such data either by transmitter 50 or by hardwire. The transmission of this data may serve to activate or “wake up” control unit 18. The non-transmission of this data may serve to deactivate and place on “standby” control unit 18, thereby avoiding the high pitch sound that results from operation of the noise cancellation system at low engine loads. Rather than use the non-transmission of data as a signal to control unit 18 to deactivate, alternatively, engine computer 18 may transmit a frequency to control unit 18 to deactivate.

24. FIG. 2 is a flowchart by which the communication of powertrain inputs is limited. Engine computer 48 determines whether engine load is greater than a predetermined threshold. If so, then engine computer 48 transmits a pulse width modulation (PWM) or other frequency communicating powertrain input such as crank position data 30, which may comprise a multiple of engine speed and teeth number. The transmission may be by hardwire or without hardwires. It is worth noting that this manner of communication permits the use of a pulse width modulation signal or simply the transmission of a signal rather than the digital communication once required. The reception of this signal by control unit 18, shown here as a digital signal processor (DSP), instructs the control unit 18 to commence signal cancellation.

25. Alternatively, if engine computer 48 determines that engine load is less than a predetermined threshold, then engine computer 48 does not transmit any signal or transmits a signal outside of the normal operating range of the system to cause control unit 18 to go on “standby”. During the standby process, control unit 18 may run a diagnostic program or self-check to ensure proper functioning of the system. Such a diagnostic program or self-check is run only if the ignition of the vehicle is “on”.

26. When control unit 18 is activated to cancel noise, speaker 14 produces a noise cancellation signal as known in the art. The noise cancellation signal is typically out of phase with the engine noise. The embodiments of the invention serve to provide a system to communicate the powertrain inputs needed to cancel engine noise in a simplified manner. In this way, engine noise is thereby attenuated.

27. The aforementioned description is exemplary rather then limiting. Many modifications and variations of the present invention are possible in light of the above teachings. The preferred embodiments of this invention have been disclosed. However, one of ordinary skill in the art would recognize that certain modifications would come within the scope of this invention. Hence, within the scope of the appended claims, the invention may be practiced otherwise than as specifically described. For this reason the following claims should be studied to determine the true scope and content of this invention.

What is claimed is:

1. An air induction system comprising:
an air intake;
a speaker disposed about said air intake;
a control unit in communication with said speaker; and
a non-hardwired receiver in communication with said control unit.

2. The air induction system of claim 1 wherein said non-hardwired receiver receives at least one powertrain input.

3. The air induction system of claim 2 wherein said at least one powertrain input is crank position data.

4. The air induction system of claim 2 wherein said at least one powertrain input is fuel injection data.

5. The air induction system of claim 2 wherein said at least one powertrain input is ignition data.

6. The air induction system of claim 1 further including a sensor monitoring said at least one powertrain input and in communication with said non-hardwired receiver.

7. The air induction system of claim 6 farther including a transmitter in communication with said sensor and in communication with said non-hardwired receiver.

8. The air induction system of claim 1 further including a microphone in communication with said control unit.

9. The air induction system of claim 2 further including an engine computer communicating said at least one powertrain input to said non-hardwired receiver.

10. The air induction system of claim 9 wherein said engine computer communicates said at least one powertrain input at a predetermined threshold.

11. An air induction system comprising
an air intake;
a speaker disposed about said air intake;
a control unit in communication with said speaker; and
an engine computer in communication with said control unit and at least one powertrain input, communicating said at least one powertrain input to said control unit at a predetermined threshold.

12. The air induction system of claim 11 wherein said predetermined threshold is based on engine load.

13. The air induction system of claim 11 wherein said at least one powertrain input is engine crank position data.

14. The air induction system of claim 11 wherein said at least one powertrain input is fuel injection data.

15. The air induction system of claim 11 wherein said at least one powertrain input is ignition data.

16. The air induction system of claim 11 further including at least one non-hardwired receiver in communication with said control unit wherein said non-hardwired receiver receives said at least one powertrain input.

17. An air induction system comprising:
an air intake;
a speaker disposed about said air intake;
a control unit in communication with said speaker;
at least one non-hardwired receiver in communication with said control unit and in reception of at least one powertrain input; and
an engine computer communicating said at least one powertrain input to said non-hardwired receiver at a predetermined threshold based on engine load.

18. The air induction system of claim 17 wherein said at least one powertrain input is engine crank data.

19. The air induction system of claim 17 wherein said at least one powertrain input is fuel injection data.

20. The air induction system of claim 17 wherein said at least one powertrain input is ignition data.
